(19) United States
(12) Patent Application Publication
(10) Pub. No.: US 2025/0308911 A1
(43) Pub. Date: Oct. 2, 2025

(54) METHOD AND CARRIER SUBSTRATE FOR PRODUCING A SEMICONDUCTOR COMPONENT

(71) Applicant: JENOPTIK Optical System GmbH, Jena (DE)

(72) Inventors: Daniel GRIMM, Jena (DE); Lutz RAUPACH, Jena (DE); Meik PANITZ, Jena (DE); Sabine ZYBELL, Jena (DE); Martin TILKE, Jena (DE)

(73) Assignee: JENOPTIK Optical System GmbH, Jena (DE)

(21) Appl. No.: 18/865,303

(22) PCT Filed: May 9, 2023
(86) PCT No.: PCT/EP2023/062276

§ 371 Date: Nov. 12, 2024

(30) Foreign Application Priority Data
May 12, 2022 (DE) 10 2022 111 943.2

(51) Int. Cl. H01L 21/306; H01L 21/3065

(52) U.S. Cl. CPC H01L 21/30604; H01L 21/3065

(57) ABSTRACT

A method of producing a semiconductor component having at least one exposed membrane section. A semiconductor material is provided having a carrier substrate provided with a passivation layer, where there is a membrane ply which is disposed atop the passivation layer and includes a material which is variable by water, in particular hydrolyzable, where the membrane ply is covered by a protective layer on an opposite side from the passivation layer. A portion of the carrier substrate is removed using a wet-chemical method in order to obtain an exposed region of the passivation layer in a structured region of the semiconductor material. A section of the membrane ply is exposed in the structured region by means of a first dry etching step for etching of the passivation layer and a second dry etching step for etching of the protective layer, in order to obtain the exposed membrane section.

The present invention relates to a method and to an apparatus for production of a semiconductor component according to the main claims.

With regard to the production of semiconductor components with membranes, DE 10 2011 005 249 A1 discloses an apparatus for conversion of mechanical energy to electrical energy and a method of production thereof. This describes the production of a curved piezoelectric membrane.

JP 2013-160706A discloses a flow detector on a semiconductor substrate with an exposed sensor region.

For modern semiconductor components, high flexibility is often a prerequisite with regard to the material properties, such that, for example, in the case of optical semiconductor components, good steering of a beam of light can be achieved. A semiconductor component in the context of this invention may mean a component which is produced on a semiconductor substrate as carrier substrate, for example a semiconductor wafer, for example a silicon wafer. This may be a mechanical and/or optical component, in which the semiconductor properties of the substrate may possibly be irrelevant in respect of function. This may be a mechanical component, an optical component, or a component for the NIR region, the visible region, the UV region, the EUV region or the x-ray region of electromagnetic waves. Such semiconductor components may be produced using typical techniques in the semiconductor industry. A problem here, however, is that some advantageous material properties are to some degree possessed by material types that can be processed only with difficulty. For example, a material may have a good, desirable material property such as a particular refractive index that can interact particularly favorably at an interface with the other material, for example air, and hence can enable particularly good steering or forming of electromagnetic radiation. At the same time, precisely this material, however, may also be water-soluble or hydrolyzable, for example, such that some method steps used in conventional semiconductor production methods cannot be used in order to process such a material.

Proceeding from this statement of the problem, a means of enabling improved processing and hence the production of a semiconductor component having improved properties is now presented.

This object is achieved by the subject matter of the main claims.

The approach presented here presents a method of producing a semiconductor component having at least one exposed membrane section, wherein the method comprises the following steps:
providing a semiconductor material having a carrier substrate provided with a passivation layer, where there is a membrane ply which is disposed atop the passivation layer and includes or consists of a material which is variable in terms of its structure and/or composition by water, in particular hydrolyzable, where the membrane ply is covered by a protective layer on an opposite side from the passivation layer;
removing a portion of the carrier substrate using a wet-chemical method in order to obtain an exposed region of the passivation layer in a structured region of the semiconductor material; and
exposing a section of the membrane ply in the structured region by means of a first dry etching step for etching of the passivation layer and a second dry etching step for etching of the protective layer, in order to obtain the exposed membrane section (140).

A carrier substrate may mean, for example, a conventional substrate, for example composed of silicon. This carrier substrate may be provided with a passivation layer which comprises silicon nitride, for example, or consists of such a material. A membrane ply may mean a layer that has a particularly advantageous property, for example with regard to its optical characteristics, but includes or consists of a material which is variable in terms of its structure and/or composition by water, in particular hydrolyzable. For example, a mechanical structure of this material can be degraded when the material comes into contact with water or a layer of this material breaks or tears. Hydrolyzing may mean intercalation between water molecules, in which case this material can then precipitate out or crystallize again in the event of evaporation or vaporization of the water. In the case of hydrolyzing, it is alternatively possible for the material to be broken down chemically by contact with water. Aluminum nitride can be hydrolyzed, for example, with formation of ammonia. A protective layer in the present context may mean a cover of the membrane ply. In this case, the protective layer and the passivation layer, which favorably consist of a water-insoluble material or one which is not variable in terms of its structure and/or composition by water, or contain this material, may ensure that the membrane ply is sealed in a fluid-tight manner from an environment of the semiconductor component (up to, for example, lateral edges of the wafer). In this way, it is possible to ensure that the membrane ply is not damaged on processing or structuring of regions of the carrier substrate or of the semiconductor component, and hence the semiconductor component to be manufactured would not be destroyed. A wet-chemical method may mean one or more process steps of a wet etching method or a wet cleaning method in which a liquid etchant and/or detergent is used to introduce structures into the semiconductor material or to clean a surface of the semiconductor material. A dry etching method may mean a process step in which the semiconductor material is structured using a physical or mechanical material removal method or using a gaseous etchant. Moreover, it is possible but not obligatory for the first and second dry etching steps to be executed by an identical dry etching method and/or to be performed in one process step. Likewise advantageous are two successively executed dry etching steps on one side each of the semiconductor component. It is also possible for the sequence of the steps of providing, removing and exposing to be advantageously effected in the sequence specified, in which case the first and second dry etching steps are executed as component steps of the exposing step and may also be performed in any sequence.

The approach proposed here offers the advantage of ensuring, by the use of the different etching or cleaning methods in different processing stages, that the membrane ply, which made of a is sensitive to an etching or cleaning material used in one of the process steps, remains substantially undamaged. In this way, it is then also possible to use a material for the membrane ply which is very favorable for the function of the semiconductor component to be produced. That which is proposed here thus enables distinct flexibilization in the use of different materials, which has very advantageous properties for a desired target use of the semiconductor component.

An advantageous embodiment of the approach proposed here is one in which, in the providing step, a semiconductor material is provided, in which the protective layer together with a cover ply forms a layer stack as protective ply, wherein a material in the protective layer differs from a material in the cover ply, especially wherein the material in the cover ply includes a reflective material and/or a metal. Such an embodiment offers the advantage of enabling, by virtue of the different materials of the layers of the protective layer, to undertake structuring of this protective layer in a very flexible manner, such that, even in a later process step, flexible configuration of the exposed membrane ply can be achieved. By virtue of the use of a reflective material for the cover ply, it is also possible, for example, to achieve desired optical properties of the finished semiconductor component. It is also possible in one embodiment for the method also to comprise a step of structuring the protective ply which is to be performed before the second dry etching step, especially before the step of removing a portion of the carrier substrate, and in which the protective layer is exposed at least in parts by removing the cover ply, especially using an auxiliary mask by means of one of the etching methods (for example a dry etching method used in the first or second dry etching step) or a further etching method (for example the further or another dry etching method).

In a further embodiment of the approach proposed here, in the structuring step, a section of the carrier substrate in the structured region can be removed. Such an embodiment of the approach proposed here offers the option of using known efficient processing steps to prepare the semiconductor material or the semiconductor component in such a way that exclusively the dry etching method can be used in the subsequent exposure step. In this way, it is possible by means of prior processing of the semiconductor material to prevent any surface of the membrane ply which is then possibly already exposed from being damaged by an etchant or detergent which is too aggressive for the material of the membrane ply.

A particularly advantageous embodiment of the approach proposed here is one in which the structuring step is executed in such a way that the membrane ply is sealed by the passivation layer and at least part of the protective layer against an etchant or detergent in the wet-chemical process. Such an embodiment offers the advantage of reliably protecting the membrane ply against the etchant in the wet-chemical process and hence preventing damage to the membrane ply.

In a further embodiment of the approach proposed here, in the exposure step, the passivation layer and at least some of the protective layer can be removed by the dry etching method. Such an embodiment of the approach proposed here offers the advantage that the dry etching method is already employed in a first exposure of the membrane ply, and this allows the membrane ply to be protected as well as possible and structured efficiently.

Semiconductor components of a particularly intricate configuration which is efficient for an end use may then be produced when the membrane ply itself is also not only exposed but also structured. For this purpose, for example, passage holes may be introduced into the membrane ply, for example in order to enable implementation of an attenuator of electromagnetic radiation or an optical structure, for example a stop structure, in the membrane ply in the exposed membrane section. Such a stop structure may have passage holes having a greater diameter than a design light wavelength of the component, in order to form conventional stops. In a particularly favorable embodiment, it is therefore possible in the exposure step to at least partly remove the membrane ply in order to obtain a perforated exposed membrane section, especially wherein a structured region of the protective layer and/or a resist mask applied to the protective layer and/or to the cover ply can be used as an etch mask. Such a perforation may have perforation holes having a greater diameter than a design light wavelength of the component, in order to form conventional stops. It is also possible for perforation holes having a smaller diameter than a design light wavelength of the component to be provided, in order thus to produce evanescent light waves or to act as a shortpass filter. The perforated membrane section may constitute a diffraction grating. It should be pointed out that light in the context of this invention may also mean EUV/XUV radiation, UV radiation, visible light and infrared light. The optical function of the component (design light wavelength) may be provided in each of the wavelength ranges specified.

Moreover, in a further embodiment of the approach presented here, in the structuring and exposing step, the membrane ply, the carrier substrate, the protective layer, a masking layer and the passivation layer can be removed in a passage region laterally adjacent to the structured region, such that an opening is formed, into which no section of the membrane ply projects. Such an embodiment of the approach proposed here offers the advantage that the method presented here can also be used to structure other regions of the semiconductor material in which no exposed sections of the membrane ply are required. In this way, the structuring of the semiconductor material or of the semiconductor component can be undertaken in a compact manner with few work steps, which allows a reduction in production costs and production time.

Another particularly favorable embodiment is one in which, in the structuring step, a holding material is applied to a section of the passivation layer that has been exposed in the passage region, wherein, in the exposure step, after removal of the carrier substrate and the passivation layer in the passage region, the holding material is removed to form the opening. A holding material may mean, for example, a polymer material, for example a photoresist, that can also be used for introduction of structures in different layers of the semiconductor material. It is also possible for the holding material to be applied together with a further material to a surface of the semiconductor material or the semiconductor component. The use of such a semiconductor material, which is applied directly to the passivation layer for example, can prevent flakes or fragments of a layer to be removed from falling into the processing space in an uncontrolled manner and causing faults in a subsequent step. Instead, such fragments that can arise from continuous reduction of the thickness of the layer to be removed can be stabilized or cohesively held by the holding material, such that residue-free removal or dissolution of these fragments becomes possible. The holding material May advantageously be applied here to the side of the passivation layer remote from the substrate in the region of the envisaged passage region.

It is also possible in a very flexible manner to use an embodiment of the approach proposed here in which, in the exposure step, the opening is formed in such a way that it has a greater diameter than an opening in the exposed region of membrane ply. Such an embodiment offers the advantage of enabling introduction of structures of different dimensions into the semiconductor material by a uniform method or process, such that the realization of desired functions in a semiconductor element can be implemented efficiently.

A semiconductor component having particularly advantageous properties can especially be realized when, in the providing step, a semiconductor material in which the passivation layer and/or a masking layer at least partly includes a silicon nitride and/or in which the membrane ply at least partly includes an aluminum nitride, a germanium oxide and/or an aluminum oxide, and/or wherein the cover ply comprises a metal, especially chromium, and/or the protective layer comprises a silicon and/or silicon nitride is provided. In this way, it is possible to realize semiconductor components of very advantageous configuration specifically for optical applications.

In an embodiment that can be used particularly advantageously for the realization of the different steps of the approach proposed here, the wet-chemical method conducted in the structuring step is a wet etching method using potassium hydroxide or tetramethylammonium hydroxide as etchant and/or a wet-chemical cleaning method, and/or in the exposure step, a dry etching method is conducted using a physical dry etching method, a chemical dry etching method and/or a physicochemical dry etching method.

The thickness of the membrane ply may advantageously be between 5 nm and 1000 nm, particularly advantageously between 10 nm and 500 nm and very particularly advantageously between 50 nm and 200 nm. The lateral extent of the exposed region of the membrane may advantageously be between 50 μm and 5000 μm, particularly advantageously between 100 μm and 500 μm. The membranes may be perforated, for example with a hole pattern, the lateral hole separations of which are between 50 nm and 5000 nm, advantageously 100 nm to 1000 nm. The membranes may be used, for example, for absorption and/or diffraction of electromagnetic rays.

In another favorable embodiment of the approach presented here, the structured region of the semiconductor material has edges, the normal of which has an angle of less than 60°, especially 54.7°, to a surface normal of the carrier substrate, especially wherein the semiconductor material is monocrystalline and the edges are formed by etch-resistant crystal planes. For example, it is possible to use a silicon wafer with a {100} surface. If the edges are formed by {111} and equivalent crystal faces, the angle may be 54.74°.

These variants of methods may be implemented, for example, in software or hardware or in a mixed form of software and hardware, for example as control commands in a control device or an apparatus.

The approach presented here also provides an apparatus designed to perform, actuate or implement the steps of a variant of a method presented here in corresponding devices. This execution variant of the invention in the form of an apparatus can also achieve the object underlying the invention in a rapid and efficient manner.

For this purpose, the apparatus may have at least one computation unit for processing of signals or data, at least one storage unit for storage of signals or data, at least one interface to a sensor or an actuator for importing sensor signals from the sensor or for exporting of data signals or control signals to the actuator, and/or at least one communication interface for importing or exporting of data embedded in a communication protocol. The computation unit may, for example, be a signal processor, a microcontroller or the like, where the storage unit may be a flash memory, an EEPROM or a magnetic storage unit. The communication interface may be designed for wireless and/or wired import or export of data, and a communication interface that can import or export wired data is able to import these data, for example electrically or optically from a corresponding data transmission wire or export them into a corresponding data transmission wire.

An apparatus in the present context may mean an electrical device that processes sensor signals and gives out control signals and/or data signals depending thereon. The apparatus may have an interface that may be in the form of hardware and/or software. In hardware form, the interfaces may, for example, be part of what is called a system ASIC, which includes a wide variety of different functions of the apparatus. However, it is also possible that the interfaces are dedicated integrated circuits or at least partly consist of discrete components. In software form, the interfaces may be software modules that are present, for example, in a microcontroller alongside other software modules.

Also advantageous is a computer program product or computer program comprising program code, which may be stored on a machine-readable carrier or storage medium, such as a semiconductor memory, a hard drive or an optical storage medium, and is used for performance, implementation and/or actuation of the steps of the method according to any of the above-described embodiments, especially when the program product or program is executed on a computer or an apparatus.

Working examples of the approach presented here are shown in the drawings and elucidated in detail in the description that follows. The figures show:

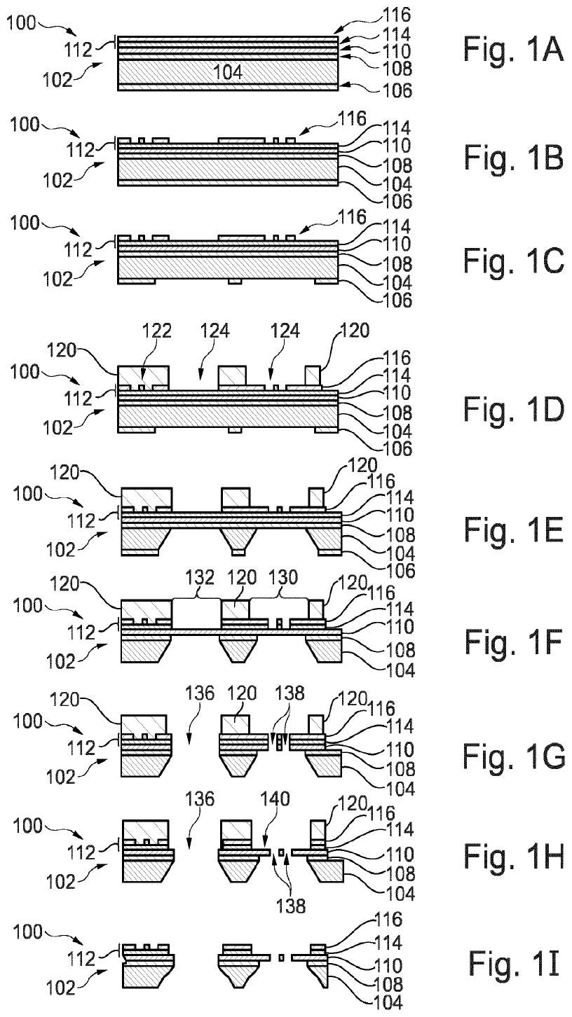

FIG. 1A to FIG. 1I multiple part-diagrams that each show a cross section of a semiconductor component to be produced according to one working example in different process steps;
a block diagram of an apparatus according to one working example;

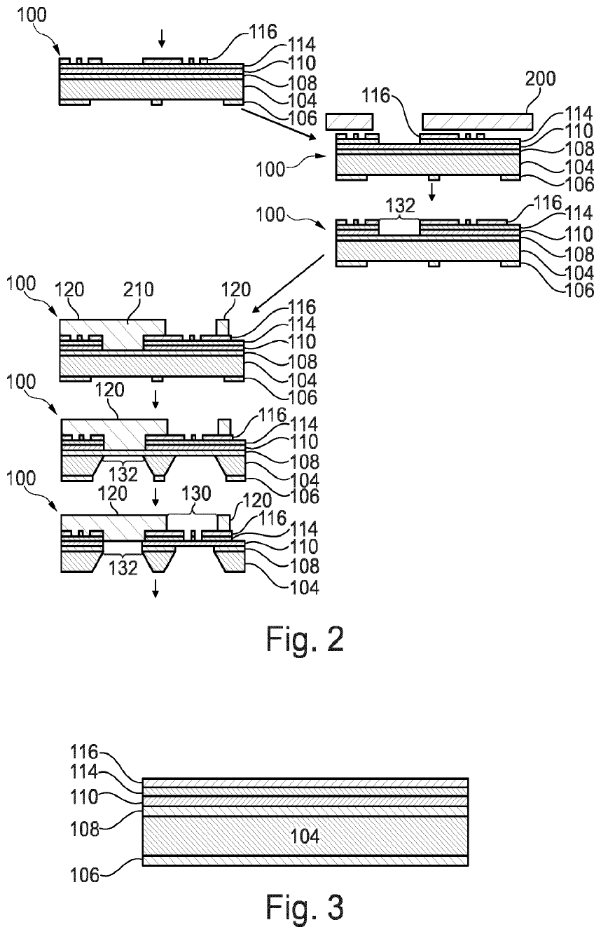

FIG. 2 multiple part-diagrams that each show a cross section of a semiconductor component to be produced according to a further working example in different process steps;

FIG. 3 a schematic cross section of the layer stack used as starting material for the semiconductor component;

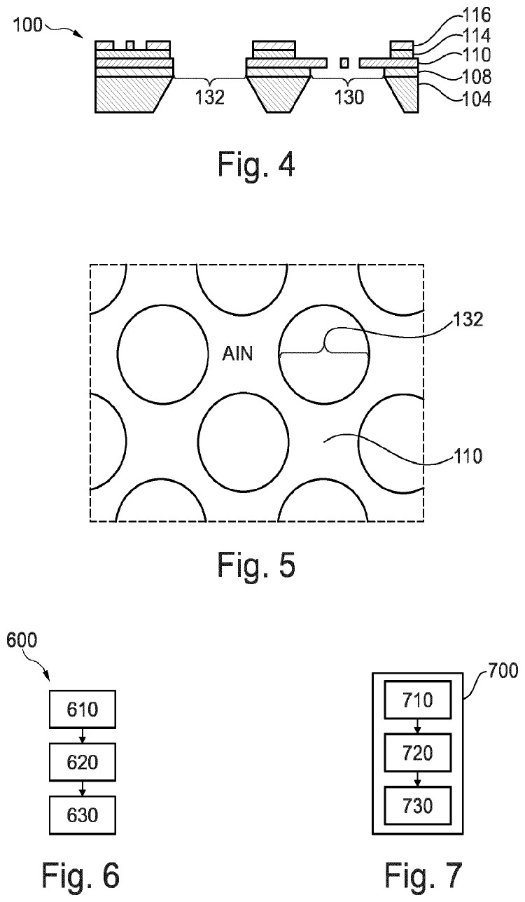

FIG. 4 a cross section of a structured wafer as starting material of a semiconductor material for the semiconductor component;

FIG. 5 a diagram of an SEM image of a structured AlN membrane that has been produced by the process procedure proposed;

FIG. 6 a flow diagram of a working example of a method of producing a semiconductor component; and

FIG. 7 a block diagram of a working example of an apparatus for production of a semiconductor component.

In the description of favorable working examples of the present invention that follows, identical or similar reference numerals are used for the elements that are shown in the different figures and have similar effects, without a repeated description of these elements.

FIG. 1 shows, in each of several part-diagrams reproduced as FIG. 1A to FIG. 1I, a cross section of a semiconductor component 100 to be produced according to one working example after different process steps.

FIG. 1A firstly shows a semiconductor material 102 in the form of a stack of several plies. This semiconductor material 102 comprises a carrier substrate 104 produced from silicon, for example, or comprising said material. The semiconductor substrate 104 further comprises a lower masking layer 106 and a passivation layer 108, each of which includes a silicon nitride (Si₃N₄), for example, or comprises said material. The masking layer 106 and the passivation layer 108 may be formed on the carrier substrate 104, for example, in the same production step. The membrane layer 110 is disposed atop the passivation layer 108 and, for example, comprises a water-soluble material or consists of such a material. Alternatively or additionally, the membrane ply 110 or may consist of a material which is variable in terms of its structure and/or composition by water, in particular hydrolyzable. A protective ply 112 is disposed atop the membrane ply 110 and comprises, for example, a protective layer 114 and a cover ply 116 disposed atop the protective layer 114. This protective layer 114 here may include a silicon-based semiconductor material and take the form of an etch stop layer. The cover ply 116 may, for example, comprise a reflective material and/or metal, for example chromium, or consist of such a material.

In a first processing step, for example, the cover ply 116, for example the reflective material, is structured, for which it is possible to use a photoresist, for example, which is exposed into the cover ply 116 in accordance with a structure to be applied. For the structuring of the cover ply 116, it is possible to use a wet etching method, and also, alternatively or additionally, a dry etching method.

FIG. 1B shows a cross-sectional diagram through a semiconductor component 100 in a state after execution of the aforementioned method steps.

This is followed, in this working example, by structuring of the masking layer 106, for example likewise again using a photoresist to be exposed and/or using a wet etching method or alternatively a dry etching method.

FIG. 1C shows a cross-sectional diagram through a semiconductor component 100 in a state after execution of this method step.

In a further method step, structuring is effected using a photoresist as etch mask 120, in order to achieve different grating types in the semiconductor component 100. In this way, it is possible to structure a substrate grating type 122 and, secondly, in a further region, a membrane grating 124.

FIG. 1D shows a cross-sectional diagram through a semiconductor component 100 in the state after execution of this method step.

In the working example of the production of the semiconductor component 100 shown in FIG. 1, in a further method step, etching through the carrier substrate 104 is then effected using a wet etching method. It is possible here by the use of the wet etching method through the openings of the masking layer 106 in the carrier substrate to form flanks that drop obliquely rather than trenches, as enabled by the use of the wet etching method with appropriate alignment of the crystal structure of the carrier substrate 104. The formation of such flanks is very advantageous for optical applications, as will be elucidated in detail hereinafter. The etching then proceeds as far as reverse-side exposure of the passivation layer 108, which serves as stop layer for the wet etching method. In this way, it is possible to avoid attack and hence damage or destruction of the water-soluble or water-sensitive membrane ply 110 by the wet etching method.

FIG. 1E shows a cross-sectional diagram through a semiconductor component 100 in the state after execution of this method step. At the same time, this state of the semiconductor component 100 is the final state in this working example of the production that can be processed by a step of the wet etching method. The subsequent steps are effected using the dry etching method in order to avoid damage or destruction of the membrane ply 110 that consists of the water-soluble material or comprises said material.

In a subsequent step, it is possible to remove sacrificial layers which, in the present working example, be the exposed part of the passivation layer 108 from the reverse side of the carrier substrate 104, and also the part of the protective layer 114 not covered by the photoresist as etch mask 120 and/or the cover ply 116. A dry etching method is used for this removal, since the membrane ply 110 is then exposed in a structured region 130 and in a passage region 132. The use of a process step of a wet etching method would also attack and damage the membrane ply 110 in this state, and so, according to the approach presented here, only a dry etching method may be used from this stage of the method onward for processing of the semiconductor component 100.

FIG. 1F shows a cross-sectional diagram through a semiconductor component 100 in the state after execution of this method step.

This may be followed, in a further method step, for example, by the removing of the membrane ply 110 in the passage region 132, such that a broad opening 136 through the semiconductor component 100 is created here. In addition, it is also possible in the structured region 130 to remove the membrane ply 110 exposed by the structured protective ply 112, specifically the structured protective layer 114 and the structured cover ply 116, which can be achieved, for example, by a dry etching method acting from above. In this way, it is possible to structure the membrane ply 110 comprising the water-soluble or water-sensitive material as desired. At the same time, it is also possible to realize very fine structures, for example holes 138, in the structured region 130 in the membrane ply 110, which makes it possible, for example, to form the exposed membrane ply 110 to be produced subsequently as a movable element.

FIG. 1G shows a cross-sectional diagram through a semiconductor component 100 in the state after execution of this method step.

Moreover, in a subsequent step, (dry) etching or removal of the region of the protective ply 112 that is not covered by the etch mask 120 is effected, i.e. of the region of the uncovered portion of the protective layer 114 and of the cover ply 116, which creates an exposed membrane section 140 of the membrane ply 110, which, for example, also has fine structures such as passage holes 138. These passage holes 138 may also be distinctly smaller in their diameter than the opening 236 in the passage region 132.

FIG. 1H shows a cross-sectional diagram through a semiconductor component 100 in the state after execution of this method step.

Finally, in a subsequent step, removal or (dry) etching of the etch mask 120 and optionally separation of the individual parts of the semiconductor component 100 are effected.

FIG. 1I shows a cross-sectional diagram through a semiconductor component 100 in the state after execution of this method step.

The sub-figures of FIG. 1 thus show a scheme of the working example of a process sequence for production of self-contained, moisture-sensitive, structured membranes using sacrificial protective layers and standard CMOS process steps. During all critical steps, the sensitive layers such as the membrane ply 110 are protected, which enables use of the wet and hence inexpensively implementable process steps.

By the approach presented here, it is thus possible to undertake the production of ultrathin, self-contained and structured membranes as membrane ply 110 from layer material which is sensitive in wet methods. In this way, it is nevertheless possible to efficiently realize the production of self-contained, ultrathin membranes, which generally entails many wet-chemical process steps of wet-chemical methods, such as lithography and wafer cleaning. For production of the self-contained membranes, the whole wafer is generally etched through by dry or wet etching. While the dry etching methods such as DRIE (deep reactive ion etching) result in approximately vertical etch profiles through the wafer, wet etching methods may also result in oblique etching profiles in the etched groove. For optical applications, an oblique V-shaped side wall with wet etching is preferred in order thus to transmit light having high NA (numerical aperture) through a membrane without shadowing on the side walls of the wafer hole. However, the use of wet etching methods is, however, difficult or impossible when the application requires a membrane material sensitive to wet chemistry. For example, aluminum-or germanium-based materials may even be water-soluble and are therefore unsuitable for most wet methods. In the approach presented here, by contrast, a process sequence that enables the production of virtually any self-contained membrane material is presented. Additionally described is a method of producing structured membranes.

The production of self-contained membranes is a widely used technology for MEMS products or optical sensors, for example. Normally, robust materials such as SiN or metals are used as membrane material or material for the membrane ply 110. Depending on the application, however, the use of more sensitive materials is also desirable. For GeO, AlN or AlₓO_{y} are, for example, good candidates for transmissive UV and EUV applications owing to good matching of the refractive index compared to vacuum. However, these materials are even water-soluble, and so a wet process step is not directly possible. What is now presented here is a method by which self-contained membranes that are made from virtually any structured and wet-sensitive material and also have an oblique side wall of the etched hole through the wafer can be produced. It consists of various sacrificial layers that protect the sensitive layer of the membrane ply 110 from the wet environment. This approach makes it possible to structure the membranes, and a suitable reflective material for sensor purposes in the VIS region. There are no restrictions in respect of the precision of structuring apart from the resolution limit of the lithography and etching tool used. Here we show a minimum structure size <200 nm, which is within the resolution limit of the tool.

The approach presented here can be used particularly advantageously for the production of self-contained ultrathin membranes from a material of particular suitability for the UV and EUV region. This material, especially AlN, is water-soluble or hydrolyzable, especially in the case of thin layers, and is not robust in the cleaning chemicals that are customarily used. The process flow proposed avoids these restrictions.

The process flow proposed also in principle permits the use of any depositable and structurable materials as membrane ply, so as to open up high flexibility in the design of semiconductor components.

The process proposed is described with reference to the processing stages of the semiconductor component shown in the sub-figures of FIG. 1. It comprises various standard processing steps, for example coating, lithography, cleaning, wet and dry etching. The use of the process route proposed can be performed more wet cleaning steps, which improves the quality of the surface defects overall. In particular, it is actually possible to utilize the critical step of wet etching at least partly for the production of the membrane.

An important aspect of the proposal presented here is the use of protective layers beneath (SiN) and above the wet-sensitive layers during all wet process steps. These protective layers are ultimately etched away. The layer stack is chosen such that individual layers can be selectively etched without etching the other masking and/or protective layers. A further advantage of the approach or layer stack proposed is the possibility of adjusting the optical reflection capacity via the chosen materials and/or layer thicknesses. The introduction of the protective layer offers, for example, the option the introduction of the protective layer the option of bringing the reflection capacity virtually to zero for green light, for example, or of achieving maximum reflection capacity solely by varying the layer thickness.

In the process sequence proposed, the step between the processing stages shown in FIGS. 1F and 1G is a challenge. On etching through the last self-contained layer in order to open large holes as in the region of the passage opening 136, this layer is gradually thinned. If the remaining layer is too thin (˜a few nanometers) to remain intact, the membrane, or the membrane ply 110 here, breaks before the etching operation has ended and rolls up to form glittery material. These shreds, which may consist of the moisture-sensitive material, act as an unwanted masking layer in the subsequent processes. For that reason, a further-optimized process sequence has been developed in order to avoid this glittery material, which through the large openings.

FIG. 2 shows, in each of several part-diagrams, a cross section of a semiconductor component 100 to be produced according to one working example in different process steps. Proceeding from the processing state of the semiconductor component 100 shown in FIG. 1C, in a first intermediate step shown on the right, a shadow mask 200 is first used, which is used in a dry etching step for removal of the protective layer 114 in the passage region 132 by a dry etching method. In this way, the membrane ply 110 is exposed in the passage region 132. In a subsequent process step, the exposed membrane ply 110 is removed by a wet etching method or a dry etching method. This is then followed again by the procedure according to the diagram in FIG. 1D, except that the etch mask 120 is now additionally also applied to the exposed upper passivation layer 108. In the subsequent steps, specifically in a the transition from the processing states between the semiconductor components 100 depicted in FIGS. 1F and 1G, it is thus ensured that the upper passivation layer 108 now cannot break up into flakes (and nor can the membrane ply 110 already removed previously in the passage region 132), which can then act as erroneous optical masking.

FIG. 2 thus shows a (partly) optimized scheme for avoidance of glittery material consisting of wet-sensitive layers at large openings. Two new process steps are included to selectively etch the layers in the regions of the large membrane openings 136, i.e. the passage region 132. All other process steps are the same or very similar to the previous process sequence in FIG. 1.

Two additional process steps (shown on the right-hand side in FIG. 2) serve for selective removal of the wet-sensitive layer at the large openings. It is possible to use various etching methods. In the process scheme, we use a shadow mask by way of example, in order to open the buffer layer. All other processes correspond, for example, essentially to the sequence described above in FIG. 1. The sole difference is the use of a slightly adapted photomask in the step that leads to the semiconductor component according to FIG. 1D, in order to keep the large openings through the photoresist as etch mask 120 closed. This improved process sequence makes it possible to replace the critical step of etching through the self-contained wet-sensitive layer by process steps in which the etching is effected against a thick (self-contained) photoresist. In this way, it is possible to avoid occurrence of glittery or flaky material in the course of processing, consisting, for example, of broken ultrathin and/or wet-sensitive material.

As an example of a wet-sensitive membrane material, the feasibility of this process sequence can be shown using aluminum nitride (AlN). AlN can even be soluble in water and/or break down under the action of water to form ammonia, which constitutes a major challenge for wet process steps. In order to obtain a flat, self-contained AlN membrane, the layer tension is adjusted to a tensile stress of several hundreds of MPa. In this example have, silicon or silicon nitride was used as protective layer. The masking and reflection layer or cover ply 116 used was chromium.

FIG. 3 shows a schematic cross section of the layer stack used as starting material 102 for the semiconductor component 100, in which an illustrative layer stack is specified for production of self-contained water-soluble AlN membranes. The AlN layer is placed under tensile stress. The masking layer 106 and the passivation layer 108 may be designed, for example, as etch stop layer and may comprise, for example, Si₃N₄ layers of thickness 100 nm. The membrane ply 110 may have an AlN having a thickness of 100 nm for example. The protective layer 114 may have a thickness of 50 nm for example and take the form of SiNₓ. The cover ply 116 may take the form, for example, of a metal ply, for example of chromium, having a thickness of 100 nm for example.

The proposed process sequence avoids exposure of the water-soluble AlN to a liquid process step. The desired V-shaped trenches through the wafers are etched with dilute KOH (potassium hydroxide) or TMAH (tetramethylammonium hydroxide). The end result is that various types of markers may be produced, i.e. gratings structured in chromium for reflective sensor purposes, and gratings structured in the self-contained AlN membrane for transmission purposes. In addition, it is also possible to provide large openings, for example for cleaning purposes.

FIG. 4 shows a cross section of a structured wafer as semiconductor component 100, consisting of a reflective Cr marking, large openings that enable access to the reverse side of the wafer, and transmissive markers on the self-contained AlN membrane.

The lateral dimensions of the Cr markers and of the structured holes of the AlN membrane are limited here merely by the resolution limit of the lithography tool in combination with the dry etching tools. It is possible to realize structures having lateral dimensions of ˜100 nm. Similar results were achieved in the case of use of Al₂O₃ as membrane material, which reacts sensitively to many wet cleaning mixtures. A typical SEM (scanning electron microscope) image of a structured self-contained AlN membrane is shown in the next figure.

FIG. 5 shows a diagram of an SEM image of a structured AlN membrane 110 that has been produced by the process sequence proposed. The circles are holes in the passage region 132 in the AlN membrane, which enable a clear optical pathway through the membrane 110 and the overall wafer 104.

FIG. 6 shows a flow diagram of a method 600 of producing a semiconductor component with at least one self-contained membrane section, wherein the method includes a step 610 of providing a semiconductor material having a carrier substrate provided with a passivation layer, where a membrane ply including a material or consisting of a material which is variable in terms of its structure and/or composition by water, in particular hydrolyzable, is disposed on the passivation layer, where the membrane ply is covered by a protective layer on an opposite side from the passivation layer. In addition, the method 600 comprises a step 620 of removing a portion of the carrier substrate using a wet-chemical method, in order to obtain an exposed region of the passivation layer in a structured region of the semiconductor material. Finally, the method 600 comprises a step 630 of exposing a section of the membrane ply in the structured region by means of a first dry etching step for etching of the passivation layer and a second dry etching step for etching of the protective layer, in order to obtain the exposed membrane section.

FIG. 7 shows a block diagram of an apparatus 700 for production of a semiconductor component. The apparatus 700 comprises a unit 710 for provision of a semiconductor material having a carrier substrate provided with a passivation layer, wherein a membrane ply including a water-soluble material or consisting of such a water-soluble material is disposed on the passivation layer, where the membrane ply is covered by a protective ply on an opposite side from the passivation layer. The apparatus 700 further comprises a unit 720 for structuring the protective ply using a wet etching method, in order to obtain a structured region of the semiconductor material. Finally, the apparatus 700 comprises a unit 730 for exposure of a section of the membrane ply in the structured region using a dry etching method in order to obtain an exposed membrane section.

In summary, it should be noted that what is presently being presented is an advantageous approach for production of structured, self-contained membranes. A process flow is presented, which enables use of materials that are not robust in the conventionally used chemicals for cleaning and etching, especially water. The large material selection enables the use of membranes having a low refractive index and hence low dispersion. Also presented is an optimized process flow in order also to enable large openings without the glittery materials that typically occur when etching through the membrane.

All etching steps may be selectively possible for the respective masking layers and etch stop layers. In spite of the use of protective layers, there is the elevated risk that small defects lead to unwanted underetching or incipient etching.

Virtually any depositable and structurable material may then be used as alternative membrane layer, which increases the flexibility of the approach presented here compared to conventional process steps.

The process flow of the invention can likewise be effected advantageously for typical MEMS membranes comprising sensitive materials. Enablement of sensitive materials as membrane layer that are not realizable by the conventional method is additionally established.

1. A method of producing a semiconductor component having at least one exposed membrane section, wherein the method comprises the following steps:
providing a semiconductor material having a carrier substrate provided with a passivation layer, where there is a membrane ply which is disposed atop the passivation layer and includes or consists of a material which is variable in terms of its structure and/or composition by water, in particular hydrolyzable, where the membrane ply is covered by a protective layer on an opposite side from the passivation layer;
removing a portion of the carrier substrate using a wet-chemical method in order to obtain an exposed region of the passivation layer in a structured region of the semiconductor material; and
exposing a section of the membrane ply in the structured region by means of a first dry etching step for etching of the passivation layer and a second dry etching step for etching of the protective layer, in order to obtain the exposed membrane section.

2. The method as claimed in claim 1, wherein, in the providing step, a semiconductor material is provided, in which the protective layer together with a cover ply forms a layer stack as protective ply, wherein a material in the protective layer differs from a material in the cover ply, especially wherein the material in the cover ply includes a reflective material and/or a metal, and the method also includes a step of structuring the protective ply which is to be performed before the second dry etching step, especially before step of removing a portion of the carrier substrate, and in which the protective layer is exposed at least in parts by removing the cover ply, especially using an auxiliary mask by means of an etching method used in the first or second dry etching method or a further etching method.

3. The method as claimed in claim 2, wherein, in the structuring and exposing step, the membrane ply, the carrier substrate, the protective layer and the passivation layer are removed in a passage region laterally adjacent to the structured region, such that an opening passing through the semiconductor component is formed, especially one into which no section of the membrane ply projects.

4. The method as claimed in claim 3, wherein contamination resulting from detachment of material residues of the passivation layer to be removed is avoided in the structuring step by applying a holding material to a section of the passivation layer exposed in the passage region, wherein the holding material is removed in the exposure step after removal of the carrier substrate and the passivation layer in the passage region, in order to form the opening.

5. The method as claimed in claim 3, wherein, in the exposure step, the opening is formed such that it has a greater diameter than an opening in the exposed region of the membrane ply.

6. The method as claimed in claim 2, wherein the wet-chemical method conducted in the structuring step is a wet etching method using potassium hydroxide or tetramethylammonium hydroxide as etchant and/or wherein the first and/or second dry etching step in the exposure step is conducted using a physical dry etching method, a chemical dry etching method and/or a physicochemical dry etching method.

7. The method as claimed in claim 1, wherein several semiconductor components are produced simultaneously on the carrier substrate.

8. The method as claimed in claim 1, wherein the step of exposing a section of the membrane ply is preceded by at least one cleaning step with an aqueous detergent, especially a wet-chemical cleaning method.

9. The method as claimed in claim 1, wherein, in the exposure step, the membrane ply is at least partly removed in order to obtain a perforated exposed membrane section, in particular using a structured region of the protective layer and/or a resist mask applied to the protective layer and/or to the cover ply as an etch mask.

10. The method as claimed in claim 1, wherein, in the providing step, a semiconductor material is provided, in which the passivation layer includes a silicon nitride at least to some degree, and/or in which the membrane ply includes an aluminum nitride, a germanium oxide and/or an aluminum oxide at least to some degree, and/or wherein the cover ply comprises a metal, especially aluminum or a transition metal, especially at least one of the transition metals titanium, nickel, chromium, tantalum, tungsten, platinum, and/or the protective layer comprises silicon and/or silicon oxide and/or silicon nitride.

11. The method as claimed in claim 1, wherein the structured region of the semiconductor material has edges, the normal of which has an angle of less than 60°, especially 54.7°, to a surface normal of the carrier substrate, especially wherein the semiconductor material is monocrystalline and the edges are formed by etch-resistant crystal planes.

12. The method as claimed in claim 1, wherein the membrane ply has a thickness between 10 nm and 500 nm.

13. An apparatus set up to execute and/or actuate steps of the method as claimed in claim 1 in corresponding units.

14. A computer program set up to execute and/or actuate the steps of the method as claimed in claim 1 when the computer program is executed on a computer unit.

15. A carrier substrate for production of at least one semiconductor component having at least one exposed membrane section, having a passivation layer disposed on a first side, wherein a membrane ply is disposed atop the passivation layer and includes or consists of a material which is variable in terms of its structure and/or composition by water, in particular hydrolyzable, where the membrane ply is covered by a protective layer on an opposite side from the passivation layer, wherein the protective layer comprises silicon and/or silicon nitride, wherein the protective layer together with a cover ply forms a layer stack as protective ply, wherein a material of the protective layer ) differs from a material of the cover ply and the cover ply comprises a metal, and an etch mask for wet etching of the substrate has also been applied on a second side of the carrier substrate opposite the first side.
